(19) United States
(12) Patent Application Publication
(10) Pub. No.: US 2026/0268826 A1
(43) Pub. Date: Sep. 10, 2026

(54) DISPLAY DEVICE, GATE DRIVE CIRCUIT, SHIFT REGISTER UNIT AND DRIVING METHOD THEREOF

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Hai ZHENG, Beijing (CN); Yao HUANG, Beijing (CN); Mengmeng DU, Beijing (CN)

(21) Appl. No.: 18/993,506

(22) PCT Filed: Aug. 12, 2024
(86) PCT No.: PCT/CN2024/111427

§ 371 Date: Jan. 10, 2025

(30) Foreign Application Priority Data
Sep. 12, 2023 (CN) 202311175927.4

(51) Int. Cl. G09G 3/20; G11C 19/28

(52) U.S. Cl. CPC G09G 3/2092; G11C 19/28; G09G 2300/0408; G09G 2310/0267; G09G 2310/0286

(57) ABSTRACT

A display device, a gate drive circuit, a shift register unit and a driving method thereof. The shift register unit includes: an input sub-circuit, connected to a signal input terminal, a first clock signal terminal, and a first node; a first control sub-circuit, connected to a first power signal terminal, a second clock signal terminal, the first node, and the second node; a second control sub-circuit, connected to the first power signal terminal, the first node, and the second node; a third control sub-circuit, connected to the first power signal terminal, a second clock signal terminal, the first node, and the second node; a first output sub-circuit, connected to the first power signal terminal, the second clock signal terminal, the first node, the second node, and a first signal output terminal; and a second output sub-circuit, connected to the second power signal terminal, a third clock signal terminal, the first node, the second node, and a second signal output terminal.

### CROSS-REFERENCE TO RELATED APPLICATIONS

This application is a US national stage of international PCT Application No. PCT/CN2024/111427, filed on Aug. 12, 2024, which claims priority to Chinese patent application No. 2023111759274, filed with the Chinese Patent Office on Sep. 12, 2023, the entire contents of which are incorporated herein by reference for all purposes.

### TECHNICAL FIELD

The present application relates to the field of display technology, and in particular, to a display device, a gate drive circuit, a shift register unit and a driving method thereof.

### BACKGROUND

As a size increases, a resolution frequency increases, and scanning time of a row becomes less and less, which seriously affects image quality compensation. In traditional low-temperature polycrystalline oxide (LTPO) circuits, data writing and Vth compensation are performed at the same time. The less the scanning time for a row, the less the compensation time.

The existing gate on array (GOA) circuit cannot drive a LTPO pixel circuit well.

### SUMMARY

The present application discloses a display device, a gate drive circuit, a shift register unit and a driving method thereof.

The present application discloses a shift register unit, including:
an input sub-circuit, connected to a signal input terminal, a first clock signal terminal, and a first node, and configured to control the signal input terminal to be connected to the first node under a control of a potential of the first clock signal terminal;
a first control sub-circuit, connected to a first power signal terminal, a second clock signal terminal, the first node, and a second node, and configured to control the second clock signal terminal to be connected to the second node under a control of a potential of the first node;
a second control sub-circuit, connected to the first power signal terminal, the first node, and the second node, and configured to control the first power signal terminal to be connected to the second node under a control of the potential of the first node;
a third control sub-circuit, connected to the first power signal terminal, the second clock signal terminal, the first node, and the second node, and configured to control the first power signal terminal to be connected to the first node under a control of potential of the second node and the second clock signal terminal;
a first output sub-circuit, connected to the first power signal terminal, the second clock signal terminal, the first node, the second node, and a first signal output terminal, and configured to control the first power signal terminal to be connected to the first signal output terminal under a control of the potential of the second node, and further configured to control the second clock signal terminal to be connected to the first signal output terminal under a control of the potential of the first node; and
a second output sub-circuit, connected to the second power signal terminal, a third clock signal terminal, the first node, the second node, and a second signal output terminal, and configured to control the second power signal terminal to be connected to the second signal output terminal under a control of the potential of the second node, and further configured to control the third clock signal terminal to be connected to the second signal output terminal under a control of the potential of the first node.

Optionally, the second output sub-circuit includes:
a tenth transistor, where a control electrode of the tenth transistor is connected to the second node, a first electrode of the tenth transistor is connected to the second power signal terminal, and a second electrode of the tenth transistor is connected to the second signal output terminal; and
an eleventh transistor, where a control electrode of the eleventh transistor is connected to the first node, a first electrode of the eleventh transistor is connected to the third clock signal terminal, and a second electrode of the eleventh transistor is connected to the second signal output terminal.

Optionally, the shift register unit further includes a fourth control sub-circuit, where the fourth control sub-circuit includes a ninth transistor, a control electrode of the ninth transistor is connected to the second power signal terminal, a first electrode of the ninth transistor is connected to the first node, and a second electrode of the ninth transistor is connected to a fourth node.

Optionally, the first control sub-circuit includes:
a second transistor, where a control electrode of the second transistor is connected to the first node, a first electrode of the second transistor is connected to the first power signal terminal;
a third transistor, where a control electrode of the second transistor is connected to a second electrode of the second transistor, a first electrode of the third transistor is connected to the second clock signal terminal, and a second electrode of the third transistor is connected to the second node; and
a first energy storage unit, where one terminal of the first energy storage unit is connected between the second clock signal terminal and the first electrode of the third transistor, and the other terminal of the first energy storage unit is connected between the control electrode of the third transistor and the second electrode of the second transistor.

Optionally, the second control sub-circuit includes:
a sixth transistor, where a control electrode of the sixth transistor is connected to the first node, a first electrode of the sixth transistor is connected to the first power signal terminal and the third control sub-circuit, and a second electrode of the sixth transistor is connected to the second node.

Optionally, the third control sub-circuit includes:
a seventh transistor, where a control electrode of the seventh transistor is connected to the second node, a first electrode of the seventh transistor is connected to the first power signal terminal and the second control sub-circuit, and a second electrode of the seventh transistor is connected to an eighth transistor; and
the eighth transistor, where a control electrode of the eighth transistor is connected to the second clock signal terminal, a first electrode of the eighth transistor is connected to the seventh transistor, and a second electrode of the eighth transistor is connected to the first node.

Optionally, the first output sub-circuit includes:
a fourth transistor, where a control electrode of the fourth transistor is connected to the second node, a first electrode of the fourth transistor is connected to the first power signal terminal, and a second electrode of the fourth transistor is connected to the first signal output terminal; and
a fifth transistor, where a control electrode of the fifth transistor is connected to the first node, a first electrode of the fifth transistor is connected to the second clock signal terminal, and a second electrode of the fifth transistor is connected to the first signal output terminal.

Optionally, the first output sub-circuit further includes:
a second energy storage unit, connected between the first signal output terminal and the first node; and
a third energy storage unit, connected between the first signal output terminal and the second node.

Optionally, the input sub-circuit includes:
a first transistor, where a control electrode of the first transistor is connected to the first clock signal terminal, a first electrode of the first transistor is connected to the signal input terminal, and a second electrode of the first transistor is connected to the first node.

The present application further discloses a gate drive circuit, where the gate drive circuit includes the above-mentioned shift register unit.

The present application further discloses a driving method of a shift register unit, for driving the above-mentioned shift register unit, where the driving method includes:
controlling, by the input sub-circuit, the signal input terminal to be connected to the first node under a control of a potential of the first clock signal terminal;
controlling, by the first control sub-circuit, the second clock signal terminal to be connected to the second node under a control of a potential of the first node;
controlling, by the first output sub-circuit, the second clock signal terminal to be connected to the first signal output terminal under a control of the potential of the first node, and controlling the first power signal terminal to be connected to the first signal output terminal under a control of the potential of the second node; and
controlling, by the second output sub-circuit, the third clock signal terminal to be connected to the second signal output terminal under a control of the potential of the first node, and controlling the second power signal terminal to be connected to the second signal output terminal under a control of the potential of the second node.

The present application further discloses a display panel, including the above-mentioned gate drive circuit, where the display panel includes an active layer, a first gate layer, a second gate layer and an electrode layer.

Optionally, the fifth transistor includes a structure of a plurality of transistors connected in parallel, and the eleventh transistor includes a structure of a plurality of transistors connected in parallel.

Compared with the related art, the shift register unit of the present application is provided with a second output sub-circuit, which allows the GOA circuit to output both high-level signals and low-level signals at the same time, enabling the GOA circuit to effectively drive a LTPO pixel circuit.

It should be understood that the above general description and the below detailed description are merely exemplary and explanatory, and are not intended to limit the present application.

### BRIEF DESCRIPTION OF DRAWINGS

The accompanying drawings, which are incorporated in and constitute a part of the present specification, illustrate examples consistent with the present application and, together with the description to explain the principles of the application.

FIG. 1 is a block diagram of a shift register unit according to an embodiment of the present disclosure.

FIG. 2 is a circuit diagram of a shift register unit according to an embodiment of the present disclosure.

FIG. 3 is a working timing diagram of a shift register unit according to an embodiment of the disclosure.

FIG. 4 is a schematic diagram of an active layer of a display panel according to an embodiment of the disclosure.

FIG. 5 is a schematic diagram of an active layer and a first gate layer of a display panel according to an embodiment of the disclosure.

FIG. 6 is a schematic diagram of an active layer, a first gate layer, and a second gate layer of a display panel according to an embodiment of the disclosure.

FIG. 7 is a schematic diagram of an active layer, a first gate layer, a second gate layer, and an electrode layer of a display panel according to an embodiment of the disclosure.

Description of reference numerals: Input sub-circuit, 1; First control sub-circuit, 2; Second control sub-circuit, 3; Third control sub-circuit, 4; Fourth control sub-circuit, 5; First output sub-circuit, 6; Second output sub-circuit, 7; First transistor, T1; Second transistor, T2; Third transistor, T3; Fourth transistor, T4; Fifth transistor, T5; Sixth transistor, T6; Seventh transistor, T7; Eighth transistor, T8; Ninth transistor, T9; Tenth transistor, T10; Eleventh transistor, T11; First energy storage unit, C1; Second energy storage unit, C2; Third energy storage unit, C3; Signal input terminal, GSTV; First clock signal terminal, GCK; Second clock signal terminal, GCB; Third clock signal terminal, PCB; First power signal terminal, VGH; Second power signal terminal, VGL; First signal output terminal, GOUT; Second signal output terminal, NOUT; First node, N1; Second node, N2; Third node, N3; Fourth node, N4; Active layer, 100; First gate layer, 200; Second gate layer, 300; Electrode layer, 400.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. Implementations described in the following examples do not represent all implementations consistent with the present application. Rather, they are merely device examples consistent with some aspects of the present application as detailed in the appended claims.

The terms used in this application are merely for the purpose of describing specific embodiments, and are not intended to limit this application. Unless otherwise defined, the technical or scientific terms used in the present application shall have the usual meanings understood by those of ordinary skill in the field to which the present application belongs. It is to be understood that, “first”, “second” and similar terms used in the specification and the claims of this patent application do not indicate any sequence or importance, but are only used to distinguish different components. Similarly, “one”, “a”, and similar terms also do not indicate a quantity limitation, but indicates that there is at least one. The term “a plurality” indicates two or more, unless specifically defined otherwise. Unless otherwise stated, the terms such as “front”, “rear”, “lower”, and/or “upper” are for ease of description only and are not limited to a position or a spatial orientation. The terms such as “comprise”, “include”, or any variant thereof mean that an element or article preceded by “comprise” or “include” encompasses elements or articles and their equivalents listed after “comprise” or “include”, do not exclude the existence of other elements or articles. “connected to” or “connected with” and similar terms are not limited to physical or mechanical connections, and can include electrical connections, whether direct or indirect.

The terms used in this application are merely for the purpose of describing specific embodiments, and are not intended to limit this application. Terms like “a”, “the” and “said” in their singular forms in the present application and the appended claims are also intended to include plurality, unless clearly indicated otherwise in the context. It should also be understood that, the term “and/or” used herein indicates and includes any or all possible combinations of one or more associated listed items.

In the related art, GOA circuits cannot drive a LTPO pixel circuit well.

To solve the above technical problem, the present application provides a shift register unit, including:
an input sub-circuit 1, connected to a signal input terminal GSTV, a first clock signal terminal GCK, and a first node N1, and configured to control the signal input terminal GSTV to be connected to the first node N1 under a control of potential of the first clock signal terminal GCK;
a first control sub-circuit 2, connected to a first power signal terminal VGH, a second clock signal terminal GCB, the first node N1, and a second node N2, and configured to control the second clock signal terminal GCB to be connected to the second node N2 under a control of potential of the first node N1;
a second control sub-circuit 3, connected to the first power signal terminal VGH, the first node N1, and the second node N2, and configured to control the first power signal terminal VGH to be connected to the second node N2 under a control of potential of the first node N1;
a third control sub-circuit 4, connected to the first power signal terminal VGH, the second clock signal terminal GCB, the first node N1, and the second node N2, and configured to control the first power signal terminal VGH to be connected to the first node N1 under a control of potential of the second node N2 and the second clock signal terminal GCB;
a first output sub-circuit 6, connected to the first power signal terminal VGH, the second clock signal terminal GCB, the first node N1, the second node N2, and a first signal output terminal GOUT, and configured to control the first power signal terminal VGH to be connected to the first signal output terminal GOUT under a control of the potential of the second node N2, and further configured to control the second clock signal terminal GCB to be connected to the first signal output terminal GOUT under a control of the potential of the first node N1; and
a second output sub-circuit 7, connected to the a second power signal terminal VGL, a third clock signal terminal PCB, the first node N1, the second node N2, and a second signal output terminal NOUT, and configured to control the second power signal terminal VGL to be connected to the second signal output terminal NOUT under a control of the potential of the second node N2, and further configured to control the third clock signal terminal PCB to be connected to the second signal output terminal NOUT under a control of the potential of the first node N1.

To solve the above technical problem, the present application further provides a gate driving circuit and a display panel, including the above shift register unit.

The shift register unit according to the present application may output a high-level signal and a low-level signal at the same time, which can effectively drive a LTPO pixel circuit.

Various embodiments of the present application that are consistent with the above-mentioned creative concepts will be described in detail below.

The transistors used in the present disclosure may be a triode, a thin-film transistor, or a field-effect transistor, or other devices with the same characteristics. In embodiments of the present disclosure, in order to distinguish two electrodes except the control electrode of the transistor, one of the two electrodes is referred to as a first electrode, and the other electrode is referred to as a second electrode. The energy storage unit used in the present disclosure may be a capacitor.

In actual operation, when the transistor is a triode, the control electrode may be a base, the first electrode may be a collector, and the second electrode may be an emitter; or, the control electrode may be a base, the first electrode may be an emitter, and the second electrode may be a collector.

In actual operation, when the transistor is a thin-film transistor or a field-effect transistor, the control electrode may be a gate, the first electrode may be a drain, and the second electrode may be a source; or, the control electrode may be a gate, the first electrode may be a source, and the second electrode may be a drain.

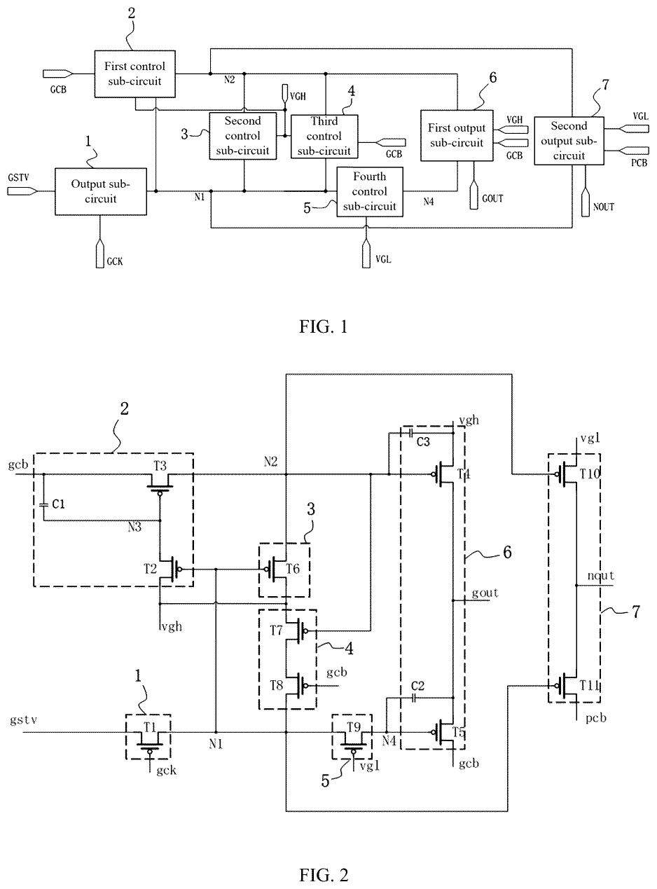

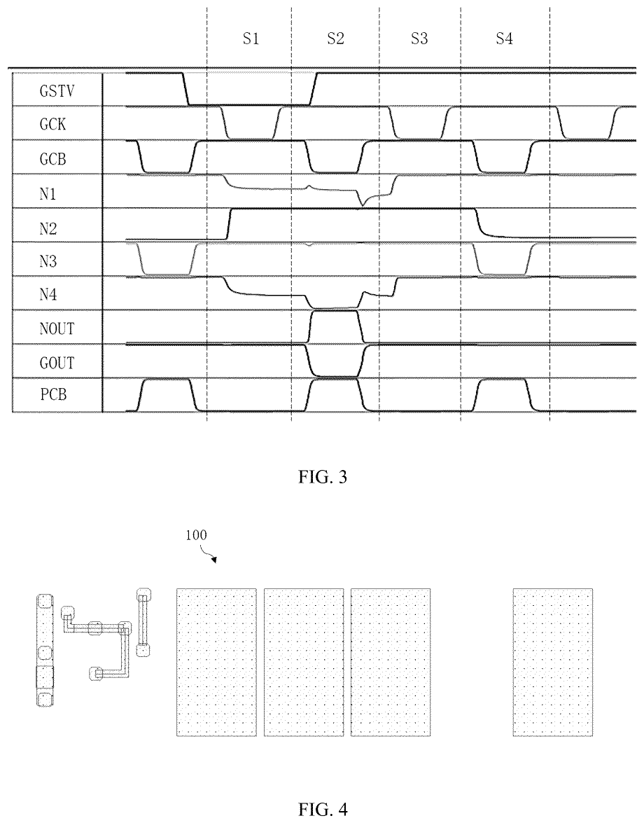

As illustrated in FIG. 1 and FIG. 2, the input sub-circuit 1 is connected to the signal input terminal GSTV, the first clock signal terminal GCK, and the first node N1, and is used to control the signal input terminal GSTV to be connected to the first node N1 under a control of potential of the first clock signal terminal GCK. In an optional embodiment, the input sub-circuit 1 includes a first transistor T1. A first electrode of the first transistor T1 is connected to the signal input terminal GSTV, a second electrode of the first transistor Tl is connected to the first node N1, and a control electrode of the first transistor T1 is connected to the first clock signal terminal GCK.

As illustrated in FIG. 1 and FIG. 2, the first control sub-circuit 2 is connected to the first power signal terminal VGH, the second clock signal terminal GCB, the first node N1, and the second node N2, and is used to control the first power signal terminal VGH to be connected to a third node N3 under a control of potential of the first node N1, and is further used to control the second clock signal terminal GCB to be connected to the second node N2 under a control of potential of the third node N3. In an optional embodiment, the first control sub-circuit 2 includes a second transistor T2. A control electrode of the second transistor T2 is connected to the first node N1, a first electrode of the second transistor T2 is connected to the first power signal terminal VGH, and a second electrode of the second transistor T2 is connected to the third node N3. The first control sub-circuit 2 further includes a third transistor T3. A control electrode of the third transistor T3 is connected to the third node N3, a first electrode of the third transistor T3 is connected to the second clock signal terminal GCB, and a second electrode of the third transistor T3 is connected to the second node N2. The first control sub-circuit 2 further includes a first energy storage unit C1. One terminal of the first energy storage unit Cl is connected between the second clock signal terminal GCB and the first electrode of the third transistor T3, and the other terminal is connected between the control electrode of the third transistor T3 and the second electrode of the second transistor T2.

As illustrated in FIG. 1 and FIG. 2, the second control sub-circuit 3 is connected to the first power signal terminal VGH, the first node N1, and the second node N2, and is used to control the first power signal terminal VGH to be connected to the second node N2 under a control of potential of the first node N1. In an optional embodiment, the second control sub-circuit 3 includes a sixth transistor T6. A control electrode of the sixth transistor T6 is connected to the first node N1, a first electrode of the sixth transistor T6 is connected to the first power signal terminal VGH, and a second electrode of the sixth transistor T6 is connected to the second node N2.

As illustrated in FIG. 1 and FIG. 2, the third control sub-circuit 4 is connected to the first power signal terminal VGH, the second clock signal terminal GCB, the first node N1, and the second node N2, and is used to control the first power signal terminal VGH to be connected to the first node N1 under a control of potential of the second node N2 and the second clock signal terminal GCB. In an optional embodiment, the third control sub-circuit 4 includes a seventh transistor T7 and an eighth transistor T8. A control electrode of the seventh transistor T7 is connected to the second node N2, a first electrode of the seventh transistor T7 is connected to the first power signal terminal VGH and the second control sub-circuit 3, and a second electrode of the seventh transistor T7 is connected to the eighth transistor T8. A control electrode of the eighth transistor T8 is connected to the second clock signal terminal GCB, a first electrode of the eighth transistor T8 is connected to the seventh transistor T7, and a second electrode of the eighth transistor T8 is connected to the first node N1.

As illustrated in FIG. 1 and FIG. 2, in an optional embodiment, the shift register unit further includes a fourth control sub-circuit 5. Optionally, the fourth control sub-circuit 5 includes a ninth transistor T9. A control electrode of the ninth transistor T9 is connected to the second power signal terminal VGL, a first electrode of the ninth transistor T9 is connected to the first node N1, and a second electrode of the ninth transistor T9 is connected to a fourth node N4.

As illustrated in FIG. 1 and FIG. 2, the first output sub-circuit 6 is connected to the first power signal terminal VGH, the second clock signal terminal GCB, the first node N1, the second node N2, and the first signal output terminal GOUT and is used to control the first power signal terminal VGH to be connected to the first signal output terminal GOUT under a control of the potential of the second node N2, and is further used to control the second clock signal terminal GCB to be connected to the first signal output terminal GOUT under a control of the potential of the first node N1. In an optional embodiment, the first output sub-circuit 6 includes a fourth transistor T4. A control electrode of the fourth transistor T4 is connected to the second node N2, a first electrode of the fourth transistor T4 is connected to the first power signal terminal VGH, and a second electrode of the fourth transistor T4 is connected to the first signal output terminal GOUT. The first output sub-circuit 6 further includes a fifth transistor T5. A control electrode of the fifth transistor T5 is connected to the first node N1, a first electrode of the fifth transistor T5 is connected to the second clock signal terminal GCB, and a second electrode of the fifth transistor T5 is connected to the first signal output terminal GOUT. The first output sub-circuit 6 also includes a second energy storage unit C2, which is connected between the first signal output terminal GOUT and the first node N1. The second energy storage unit C2 stores the signal of the first node N1. The first output sub-circuit 6 also includes a third energy storage unit C3, which is connected between the first signal output terminal GOUT and the second node N2. The third energy storage unit C3 stores the signal of the second node N2.

As illustrated in FIG. 1 and FIG. 2, the second output sub-circuit 7 is connected to the second power signal terminal VGL, the third clock signal terminal PCB, the first node N1, the second node N2, and the second signal output terminal NOUT, and is used to control the second power signal terminal VGL to be connected to the second signal output terminal NOUT under a control of the potential of the second node N2, and is also used to control the third clock signal terminal PCB to be connected to the second signal output terminal NOUT under a control of the potential of the first node N1. In an optional embodiment, the second output sub-circuit 7 includes a tenth transistor T10. A control electrode of the tenth transistor T10 is connected to the second node N2, a first electrode of the tenth transistor T10 is connected to the second power signal terminal VGL, and a second electrode of the tenth transistor T10 is connected to the second signal output terminal NOUT. The second output sub-circuit 7 also includes an eleventh transistor T11. A control electrode of the eleventh transistor T11 is connected to the first node N1, a first electrode of the eleventh transistor T11 is connected to the third clock signal terminal PCB, and a second electrode of the eleventh transistor T11 is connected to the second signal output terminal NOUT.

A working process of the shift register unit in FIG. 2 will be described in detail below, in combination with a working timing diagram of the shift register unit illustrated in FIG. 3. Taking the case where all the above transistors are P-type thin film transistors as an example, conduction levels of all the transistors are low level.

In a first phase S1, the signal input terminal GSTV outputs a low level, the first clock signal terminal GCK outputs a low level, the second clock signal terminal GCB outputs a high level, and the third clock signal terminal PCB outputs a low level. The first transistor T1 conducts, the signal input terminal GSTV is connected to the first node N1, and a low level is written to the first node N1. The ninth transistor T9 is in a normally-on state, the first node N1 is connected to the fourth node N4, and a low level is written to the fourth node N4. The second transistor T2 conducts, the first power signal terminal VGH is connected to the third node N3, and a high level is written to the third node N3. The third transistor T3 turns off, the sixth transistor T6 conducts, the first power signal terminal VGH is connected to the second node N2, and a high level is written to the second node N2. The fourth transistor T4 turns off, the fifth transistor T5 conducts, the first signal output terminal GOUT is connected to the second clock signal terminal GCB, and the first signal output terminal GOUT outputs a high-level signal. The tenth transistor T10 turns off, the eleventh transistor T11 conducts, the third clock signal terminal PCB is connected to the second signal output terminal NOUT, and the second signal output terminal NOUT outputs a low-level signal.

In a second phase S2, level output by the signal input terminal GSTV changes from a low level to a high level, the first clock signal terminal GCK outputs a high level, the second clock signal terminal GCB outputs a low level, and the third clock signal terminal PCB outputs a high level. The first transistor T1 turns off, the second energy storage unit C2 stores a low-level signal. The ninth transistor T9 is in a normally-on state, and the fourth node N4 and the first node N1 remain in a low-level state. The second transistor T2 conducts, the first power signal terminal VGH is connected to the third node N3, and the third node N3 maintains a high level. The third transistor T3 turns off, the sixth transistor T6 conducts, the first power signal terminal VGH is connected to the second node N2, and the second node N2 maintains a high level. The fourth transistor T4 turns off, the fifth transistor T5 conducts, the first signal output terminal GOUT is connected to the second clock signal terminal GCB, and the first signal output terminal GOUT outputs a low-level signal. The tenth transistor T10 turns off. The eleventh transistor T11 conducts, the second signal output terminal NOUT is connected to the third clock signal terminal PCB, and the second signal output terminal NOUT outputs a high-level signal. When the fourth node N4 and the first node N1 continue remaining in a low-level state, the signal of the second clock signal terminal GCB changes from a low-level signal to a high-level signal, and the signal of the third clock signal terminal PCB changes from a high-level signal to a low-level signal. At this time, the first signal output terminal GOUT outputs a high-level signal, and the second signal output terminal NOUT outputs a low-level signal.

In a third phase S3, the signal input terminal GSTV outputs a high level, the first clock signal terminal GCK outputs a low level, the second clock signal terminal GCB outputs a high level, and the third clock signal terminal PCB outputs a low level. The first transistor T1 conducts, the signal input terminal GSTV is connected to the first node N1, and the first node N1 changes from a low level to a high level. The ninth transistor T9 is in a normally-on state, the first node N1 is connected to the fourth node N4, and the fourth node N4 changes from a low level to a high level. The second transistor T2 turns off, the third transistor T3 turns off, and the second node N2 is not connected to the second clock signal terminal GCB. The sixth transistor T6 changes from a conductive state to an off state, and the second node N2 maintains a high level. The fourth transistor T4 turns off, and the fifth transistor T5 changes from a conductive state to an off state. The first signal output terminal GOUT and the second clock signal terminal GCB change from a connected state to a disconnected state, and the first signal output terminal GOUT maintains outputting high-level signal. The tenth transistor T10 turns off, and the eleventh transistor T11 changes from a conductive state to an off state. The third clock signal terminal PCB and the second signal output terminal NOUT change from a connected state to a disconnected state, and the second signal output terminal NOUT maintains outputting low-level signal.

In a fourth phase S4, the signal input terminal GSTV outputs a high level, the first clock signal terminal GCK outputs a high level, the second clock signal terminal GCB outputs a low level, and the third clock signal terminal PCB outputs a high level. The first transistor T1 turns off, and the second energy storage unit C2 stores a high-level signal. The ninth transistor T9 is in a normally-on state, and the fourth node N4 and the first node N1 remain in a high-level state. The second transistor T2 turns off, and the output of the second clock signal terminal GCB changes from a high level to a low level. By the first energy storage unit C1, the control electrode of the third transistor T3 is changed to a low level. The third transistor T3 conducts, the second clock signal terminal GCB is connected to the second node N2, and a low level is written to the second node N2. The seventh transistor T7 and the eighth transistor T8 conduct, the first power signal terminal VGH is connected to the first node N1, and the first node N1 remains at a high level. The fourth transistor T4 conducts, the fifth transistor T5 turns off, the first signal output terminal GOUT is connected to the first power signal terminal VGH, and the first signal output terminal GOUT outputs a high-level signal. The tenth transistor T10 conducts. The eleventh transistor T11 turns off, the second signal output terminal NOUT is connected to the second power signal terminal VGL, and the second signal output terminal NOUT outputs a low-level signal. At this point, before the next arrival of low-level of the signal input terminal GSTV, the first signal output terminal GOUT will continue maintaining a high-level output, and the second signal output terminal NOUT will continue maintaining a low-level output, so the subsequent phases are not repeated.

Embodiments of the present disclosure further provide a gate driving circuit. The gate driving circuit may include a plurality of cascaded shift register units described in any one of the above embodiments.

The present application further discloses a driving method of a shift register unit, and the driving method is used for driving the above-mentioned shift register unit. The method includes:
controlling, by the input sub-circuit, the signal input terminal to be connected to the first node under a control of potential of the first clock signal terminal;
controlling, by the first control sub-circuit, the second clock signal terminal to be connected to the second node under a control of potential of the first node;
controlling, by the first output sub-circuit, the second clock signal terminal to be connected to the first signal output terminal under a control of the potential of the first node, and controlling the first power signal terminal to be connected to the first signal output terminal under a control of the potential of the second node; and
controlling, by the second output sub-circuit, the third clock signal terminal to be connected to the second signal output terminal under a control of the potential of the first node, and controlling the second power signal terminal to be connected to the second signal output terminal under a control of the potential of the second node.

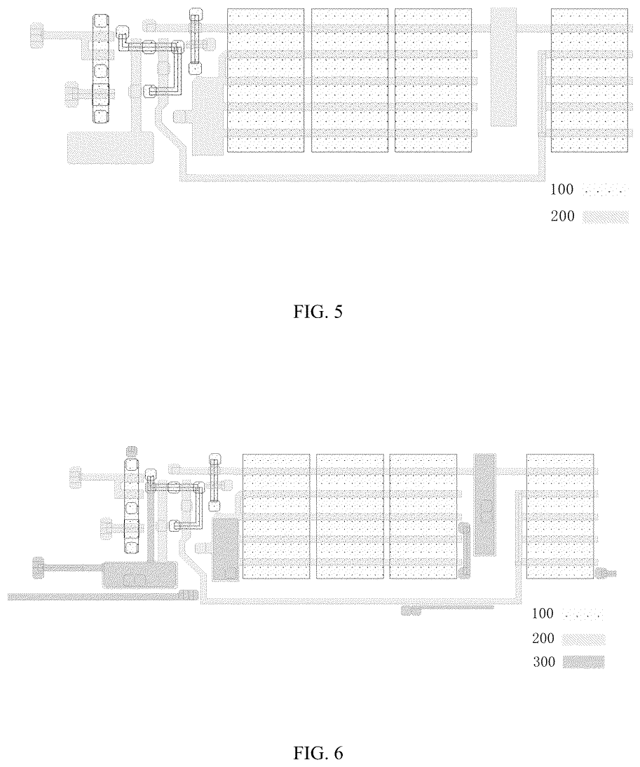

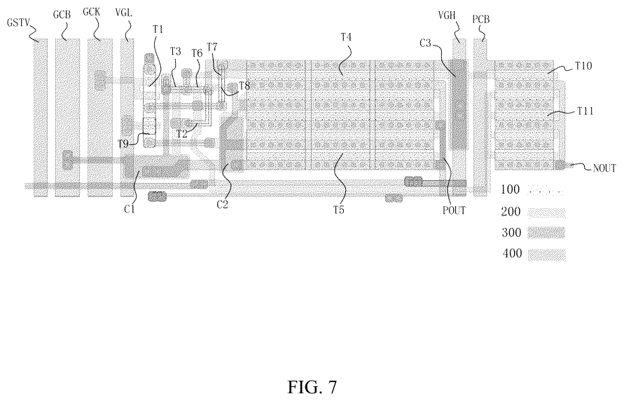

As illustrated in FIG. 4 to FIG. 7, the present application further discloses a display panel, including the above-mentioned gate drive circuit, where the display panel includes an active layer 100, a first gate layer 200, a second gate layer 300, and an electrode layer 400.

The first to eleventh transistors are formed on the active layer 100 and the first gate layer 200. The first energy storage unit C1, the second energy storage unit C2, and the third energy storage unit C3 are formed on the first gate layer 200 and the second gate layer 300. Both the fifth transistor T5 and the eleventh transistor T11 include a plurality of transistors connected in parallel. Optionally, the fifth transistor T5 includes four transistors connected in parallel, and the eleventh transistor T11 includes four transistors connected in parallel.

Those skilled in the art can think of other implementations of the present specification after considering the specification and practice of the present application herein. The present application is intended to cover any variations, uses, modification or adaptations of the present application that follow the general principles of the present specification and include common knowledge or conventional technical methods in the related art that are not disclosed in the present application. The specification and implementations are considered as examples only, true scope and spirit of the present application is indicated by the following claims.

It should be understood that the present application is not limited to the precise structure described above and shown in the accompanying drawings, and various modifications and changes can be made without departing from the scope of the present specification. The scope of the present application is limited only by the appended claims.

The above are the examples of the present application, which are not intended to limit the application. Any modification, equivalent substitution, or improvement made within the spirit and principle of the present application shall be included within the protection scope of the application.

1. A shift register unit, comprising:
an input sub-circuit, connected to a signal input terminal, a first clock signal terminal, and a first node, and configured to control the signal input terminal to be connected to the first node under a control of a potential of the first clock signal terminal;
a first control sub-circuit, connected to a first power signal terminal, a second clock signal terminal, the first node, and a second node, and configured to control the second clock signal terminal to be connected to the second node under a control of a potential of the first node;
a second control sub-circuit, connected to the first power signal terminal, the first node, and the second node, and configured to control the first power signal terminal to be connected to the second node under a control of the potential of the first node;
a third control sub-circuit, connected to the first power signal terminal, the second clock signal terminal, the first node, and the second node, and configured to control the first power signal terminal to be connected to the first node under a control of potential of the second node and the second clock signal terminal;
a first output sub-circuit, connected to the first power signal terminal, the second clock signal terminal, the first node, the second node, and a first signal output terminal, and configured to control the first power signal terminal to be connected to the first signal output terminal under a control of the potential of the second node, and further configured to control the second clock signal terminal to be connected to the first signal output terminal under a control of the potential of the first node; and
a second output sub-circuit, connected to the second power signal terminal, a third clock signal terminal, the first node, the second node, and a second signal output terminal, and configured to control the second power signal terminal to be connected to the second signal output terminal under a control of the potential of the second node, and further configured to control the third clock signal terminal to be connected to the second signal output terminal under a control of the potential of the first node.

2. The shift register unit according to claim 1, wherein the second output sub-circuit comprises:
a tenth transistor, where a control electrode of the tenth transistor is connected to the second node, a first electrode of the tenth transistor is connected to the second power signal terminal, and a second electrode of the tenth transistor is connected to the second signal output terminal; and
an eleventh transistor, where a control electrode of the eleventh transistor is connected to the first node, a first electrode of the eleventh transistor is connected to the third clock signal terminal, and a second electrode of the eleventh transistor is connected to the second signal output terminal.

3. The shift register unit according to claim 1, further comprising: a fourth control sub-circuit, the fourth control sub-circuit includes a ninth transistor, a control electrode of the ninth transistor is connected to the second power signal terminal, a first electrode of the ninth transistor is connected to the first node, and a second electrode of the ninth transistor is connected to a fourth node.

4. The shift register unit according to claim 1, wherein the first control sub-circuit comprises:
a second transistor, where a control electrode of the second transistor is connected to the first node, a first electrode of the second transistor is connected to the first power signal terminal;
a third transistor, where a control electrode of the third transistor is connected to a second electrode of the second transistor, a first electrode of the third transistor is connected to the second clock signal terminal, and a second electrode of the third transistor is connected to the second node; and
a first energy storage unit, where one terminal of the first energy storage unit is connected between the second clock signal terminal and the first electrode of the third transistor, and the other terminal of the first energy storage unit is connected between the control electrode of the third transistor and the second electrode of the second transistor.

5. The shift register unit according to claim 1, wherein the second control sub-circuit comprises:
a sixth transistor, where a control electrode of the sixth transistor is connected to the first node, a first electrode of the sixth transistor is connected to the first power signal terminal and the third control sub-circuit, and a second electrode of the sixth transistor is connected to the second node.

6. The shift register unit according to claim 1, wherein the third control sub-circuit comprises:
a seventh transistor, where a control electrode of the seventh transistor is connected to the second node, a first electrode of the seventh transistor is connected to the first power signal terminal and the second control sub-circuit, and a second electrode of the seventh transistor is connected to an eighth transistor; and
the eighth transistor, where a control electrode of the eighth transistor is connected to the second clock signal terminal, a first electrode of the eighth transistor is connected to the seventh transistor, and a second electrode of the eighth transistor is connected to the first node.

7. The shift register unit according to claim 1, wherein the first output sub-circuit comprises:
a fourth transistor, where a control electrode of the fourth transistor is connected to the second node, a first electrode of the fourth transistor is connected to the first power signal terminal, and a second electrode of the fourth transistor is connected to the first signal output terminal; and
a fifth transistor, where a control electrode of the fifth transistor is connected to the first node, a first electrode of the fifth transistor is connected to the second clock signal terminal, and a second electrode of the fifth transistor is connected to the first signal output terminal.

8. The shift register unit according to claim 7, wherein the first output sub-circuit further comprises:
a second energy storage unit, connected between the first signal output terminal and the first node; and
a third energy storage unit, connected between the first signal output terminal and the second node.

9. The shift register unit according to claim 1, wherein the input sub-circuit comprises:
a first transistor, where a control electrode of the first transistor is connected to the first clock signal terminal, a first electrode of the first transistor is connected to the signal input terminal, and a second electrode of the first transistor is connected to the first node.

10. A gate drive circuit, comprising the shift register unit according to claim 1.

11. A driving method of a shift register unit, for driving a shift register unit comprising:
an input sub-circuit, connected to a signal input terminal, a first clock signal terminal, and a first node, and configured to control the signal input terminal to be connected to the first node under a control of a potential of the first clock signal terminal;
a first control sub-circuit, connected to a first power signal terminal, a second clock signal terminal, the first node, and a second node, and configured to control the second clock signal terminal to be connected to the second node under a control of a potential of the first node;
a second control sub-circuit, connected to the first power signal terminal, the first node, and the second node, and configured to control the first power signal terminal to be connected to the second node under a control of the potential of the first node;
a third control sub-circuit, connected to the first power signal terminal, the second clock signal terminal, the first node, and the second node, and configured to control the first power signal terminal to be connected to the first node under a control of potential of the second node and the second clock signal terminal;
a first output sub-circuit, connected to the first power signal terminal, the second clock signal terminal, the first node, the second node, and a first signal output terminal, and configured to control the first power signal terminal to be connected to the first signal output terminal under a control of the potential of the second node, and further configured to control the second clock signal terminal to be connected to the first signal output terminal under a control of the potential of the first node; and
a second output sub-circuit, connected to the second power signal terminal, a third clock signal terminal, the first node, the second node, and a second signal output terminal, and configured to control the second power signal terminal to be connected to the second signal output terminal under a control of the potential of the second node, and further configured to control the third clock signal terminal to be connected to the second signal output terminal under a control of the potential of the first node, wherein the driving method comprises:
controlling, by the input sub-circuit, the signal input terminal to be connected to the first node under a control of a potential of the first clock signal terminal;
controlling, by the first control sub-circuit, the second clock signal terminal to be connected to the second node under a control of a potential of the first node;
controlling, by the first output sub-circuit, the second clock signal terminal to be connected to the first signal output terminal under a control of the potential of the first node, and controlling the first power signal terminal to be connected to the first signal output terminal under a control of the potential of the second node; and
controlling, by the second output sub-circuit, the third clock signal terminal to be connected to the second signal output terminal under a control of the potential of the first node, and controlling the second power signal terminal to be connected to the second signal output terminal under a control of the potential of the second node.

12. A display panel, comprising a gate drive circuit, wherein the display panel comprises an active layer, a first gate layer, a second gate layer and an electrode layer;
wherein the gate drive circuit comprises one or more shift register units each comprises:
an input sub-circuit, connected to a signal input terminal, a first clock signal terminal, and a first node, and configured to control the signal input terminal to be connected to the first node under a control of a potential of the first clock signal terminal;
a first control sub-circuit, connected to a first power signal terminal, a second clock signal terminal, the first node, and a second node, and configured to control the second clock signal terminal to be connected to the second node under a control of a potential of the first node;
a second control sub-circuit, connected to the first power signal terminal, the first node, and the second node, and configured to control the first power signal terminal to be connected to the second node under a control of the potential of the first node;
a third control sub-circuit, connected to the first power signal terminal, the second clock signal terminal, the first node, and the second node, and configured to control the first power signal terminal to be connected to the first node under a control of potential of the second node and the second clock signal terminal;
a first output sub-circuit, connected to the first power signal terminal, the second clock signal terminal, the first node, the second node, and a first signal output terminal, and configured to control the first power signal terminal to be connected to the first signal output terminal under a control of the potential of the second node, and further configured to control the second clock signal terminal to be connected to the first signal output terminal under a control of the potential of the first node; and
a second output sub-circuit, connected to the second power signal terminal, a third clock signal terminal, the first node, the second node, and a second signal output terminal, and configured to control the second power signal terminal to be connected to the second signal output terminal under a control of the potential of the second node, and further configured to control the third clock signal terminal to be connected to the second signal output terminal under a control of the potential of the first node.

13. (canceled)

14. The display panel according to claim 12, wherein the second output sub-circuit comprises:
a tenth transistor, where a control electrode of the tenth transistor is connected to the second node, a first electrode of the tenth transistor is connected to the second power signal terminal, and a second electrode of the tenth transistor is connected to the second signal output terminal; and
an eleventh transistor, where a control electrode of the eleventh transistor is connected to the first node, a first electrode of the eleventh transistor is connected to the third clock signal terminal, and a second electrode of the eleventh transistor is connected to the second signal output terminal.

15. The display panel according to claim 12, further comprising: a fourth control sub-circuit, the fourth control sub-circuit includes a ninth transistor, a control electrode of the ninth transistor is connected to the second power signal terminal, a first electrode of the ninth transistor is connected to the first node, and a second electrode of the ninth transistor is connected to a fourth node.

16. The display panel according to claim 12, wherein the first control sub-circuit comprises:
a second transistor, where a control electrode of the second transistor is connected to the first node, a first electrode of the second transistor is connected to the first power signal terminal;
a third transistor, where a control electrode of the third transistor is connected to a second electrode of the second transistor, a first electrode of the third transistor is connected to the second clock signal terminal, and a second electrode of the third transistor is connected to the second node; and
a first energy storage unit, where one terminal of the first energy storage unit is connected between the second clock signal terminal and the first electrode of the third transistor, and the other terminal of the first energy storage unit is connected between the control electrode of the third transistor and the second electrode of the second transistor.

17. The display panel according to claim 12, wherein the second control sub-circuit comprises:
a sixth transistor, where a control electrode of the sixth transistor is connected to the first node, a first electrode of the sixth transistor is connected to the first power signal terminal and the third control sub-circuit, and a second electrode of the sixth transistor is connected to the second node.

18. The display panel according to claim 12, wherein the third control sub-circuit comprises:
a seventh transistor, where a control electrode of the seventh transistor is connected to the second node, a first electrode of the seventh transistor is connected to the first power signal terminal and the second control sub-circuit, and a second electrode of the seventh transistor is connected to an eighth transistor; and
the eighth transistor, where a control electrode of the eighth transistor is connected to the second clock signal terminal, a first electrode of the eighth transistor is connected to the seventh transistor, and a second electrode of the eighth transistor is connected to the first node.

19. The display panel according to claim 12, wherein the first output sub-circuit comprises:
a fourth transistor, where a control electrode of the fourth transistor is connected to the second node, a first electrode of the fourth transistor is connected to the first power signal terminal, and a second electrode of the fourth transistor is connected to the first signal output terminal; and
a fifth transistor, where a control electrode of the fifth transistor is connected to the first node, a first electrode of the fifth transistor is connected to the second clock signal terminal, and a second electrode of the fifth transistor is connected to the first signal output terminal.

20. The display panel according to claim 19, wherein the fifth transistor comprises a structure of a plurality of transistors connected in parallel.

21. The display panel according to claim 14, wherein the eleventh transistor comprises a structure of a plurality of transistors connected in parallel.
